(19) United States
(12) Patent Application Publication
(10) Pub. No.: US 2019/0221639 A1
(43) Pub. Date: Jul. 18, 2019

(54) NANOSHEET DEVICE AND METHOD FOR FABRICATING THE SAME

(71) Applicant: United Microelectronics Corp., Hsinchu (TW)

(72) Inventors: Kuan-Hao Tseng, Kaohsiung City (TW); Yu-Hsiang Lin, New Taipei City (TW); Shih-Hung Tsai, Tainan City (TW); Po-Kuang Hsieh, Kaohsiung City (TW); Yu-Ting Tseng, Tainan City (TW); Chueh-Fei Tai, Tainan City (TW); Cheng-Ping Kuo, Pingtung County (TW)

(73) Assignee: United Microelectronics Corp., Hsinchu (TW)

(21) Appl. No.: 15/870,267

(22) Filed: Jan. 12, 2018

(51) Int. Cl. H01L 29/06; H01L 29/66; H01L 21/308; H01L 29/08; H01L 21/02; H01L 21/3065; H01L 29/10; H01L 21/306; H01L 29/78

(52) U.S. Cl. CPC H01L 29/0673; H01L 29/66522; H01L 21/3081; H01L 29/66553; H01L 29/0847; H01L 29/6656; H01L 21/02532; H01L 21/02546; H01L 21/3065; H01L 29/1033; H01L 21/3086; H01L 21/30604; H01L 29/66795; H01L 29/785; H01L 29/66545

(57) ABSTRACT

A method for fabrication a nanosheet device includes providing forming a stacked layer on a substrate, having first material layers and second material layers in different materials, alternatingly stacked up. The stacked layer is patterned to a stacked fin. A dummy stack is formed on the stacked fin. An etching back process is performed with the dummy stack with spacers to etch the stacked fin and expose the substrate. Laterally etches the first material layers and the second material layers, to have indent portions. Inner spacers fill the indent portions. A first/second source/drain layer is formed on the substrate at both sides of the dummy stack. Etching process is performed to remove the dummy gate of the dummy stack and the selected one of the first material layers and the second material layers between the inner spacers. Metal layer fills between the spacers and the inner spacers.

### BACKGROUND

### 1. Field of the Invention

The present invention generally relates to semiconductor fabrication, and particularly to fabrication of a nanosheet device.

### 2. Description of Related Art

An integrated circuit usually includes a large number of field effect transistors to form the circuit and/or the memory cells. As to the need to reduce the device size in the integrated circuit, the size of the transistors are the key factor to effectively reduce the device size. The structure of transistor is then further developed.

The fin field effect transistor (FinFET) has been proposed as another choice to replace the conventional structure based on the substrate. After the development to the FinFET, even further, the nanosheet device, similar to the FinFET, has been proposed to obtain the stress effect on the channel, so to improve the mobility of carriers in the semiconductor material.

The nanosheet channel is formed by multiple nanowires, stacked by the inner spacers. However, how to form the inner spacer and then form the complementary metal-oxide-semiconductor (CMOS) device with the improved performance are still under the development.

### SUMMARY OF THE INVENTION

In an embodiment, the invention provides a nanosheet transistor and the method for fabricating the nanosheet transistor. The method can be easily adapted inti the fabrication of CMOS device.

In an embodiment, the invention provides a method for fabricating a nanosheet device, comprising providing a substrate and forming a stacked layer on the substrate, having a plurality of first material layers and a plurality of second material layers in different materials, alternatingly stacked up. The stacked layer is patterned to form a stacked fin. A dummy stack is formed on the stacked fin, wherein the dummy stack comprises an insulating layer and a dummy gate sequentially stacked on the stacked fin and a pair of spacers on sidewalls of the dummy gate. An etching back process is performed with the dummy stack serving as an etching mask to etch the stacked fin and expose the substrate. A selected one of the first material layers and the second material layers is laterally etched to have a pair of indent portions. A pair of inner spacers is formed to fill the indent portions. A first source/drain layer and a second source/drain layer are formed on the substrate at both sides of the dummy stack. An etching process is performed to remove the dummy gate of the dummy stack and the selected one of the first material layers and the second material layers between the inner spacers. A metal layer is formed to fill between the spacers and the inner spacers.

In an embodiment, as to the method for fabricating a nanosheet device, a thickness of the spacer and a thickness of the inner spacer are substantially equal.

In an embodiment, as to the method for fabricating a nanosheet device, a thickness of the spacer and a thickness of the inner spacer are different.

In an embodiment, as to the method for fabricating a nanosheet device, a number of the first material layers is equal to a number of the second material layers.

In an embodiment, as to the method for fabricating a nanosheet device, a number of the first material layers is equal to a number of the second material layers, or greater than the number of the second material layers by one.

In an embodiment, as to the method for fabricating a nanosheet device, the first/second material layers include SiGe/Si, Ge/GaAs, or GaAs/AlAs.

In an embodiment, as to the method for fabricating a nanosheet device, the nanosheet device is an N-type metal-oxide-semiconductor (MOS) device, an P-type NMOS device, or a complementary MOS (CMOS) device.

In an embodiment, as to the method for fabricating a nanosheet device, the step of performing the etching process comprises a dry etching with a first etchant and a wet etching with a second etchant.

In an embodiment, a method for fabricating nanosheet device is provided, comprising: providing a substrate, having an N-type device region and a P-type device region. A stacked layer is formed on the substrate, having a plurality of first material layers and a plurality of second material layers with different material but in equal number, alternatingly stacked over the substrate. A top first material layer is formed on the stacked layer at the P-type device region. The stacked layer is patterned at an N-type device region to form a first stacked fin, and the stacked layer with the top first material layer at the P-type device region is patterned to form a second stacked fin. A dummy stack is formed on the first stacked fin and the second stacked fin, wherein the dummy stack comprises an insulating layer and a dummy gate sequentially stacked on the first and second stacked fins and a pair of spacers on sidewalls of the dummy gate. An etching back process is performed with the dummy stack serving as an etching mask to etch the first and second stacked fins and expose the substrate. The first material layers of the first stacked fin are laterally etched to have a pair of first indent portions. The second material layers of the second stacked fin are laterally etched to have a pair of second indent portions. A pair of first inner spacers is formed to fill the first indent portions and a pair of second inner spacers to fill the second indent portions. A first source/drain layer and a second source/drain layer are formed on the substrate at both sides of the dummy stack. An etching process is performed to remove the dummy gate of the dummy stack and the first material layers between the first inner spacers at the N-type device region, and remove the dummy gate of the dummy stack and the second material layers between the second inner spacers at the P-type device region. A metal layer is formed to fill between the spacers and the first inner spacers at the N-type device region and between the spacers and the second inner spacers at the P-type device region.

In an embodiment, as to method for fabricating a nanosheet device, a thickness of the first and second spacers is substantially equal to a thickness of the first and second inner spacers.

In an embodiment, as to the method for fabricating a nanosheet device, a thickness of the first and second spacers is different from a thickness of the first and second inner spacers.

In an embodiment, as to the method for fabricating a nanosheet device, the first/second material layers include SiGe/Si, Ge/GaAs, or GaAs/AlAs.

In an embodiment, as to the method for fabricating a nanosheet device, the step of performing the etching process comprises a dry etching with a first etchant and a wet etching with a second etchant.

In an embodiment, a nanosheet device is provided, comprising a substrate, having a first device region and a second device region. A plurality of second material layers is disposed at the first device region, stacked with a plurality of first inner spacers at a first edge region, wherein a first one of the first inner spacers is disposed on the substrate. A plurality of first material layers is at the second device region, stacked with a plurality of second inner spacers at a second edge region, wherein a first one of the first material layers is disposed on the substrate, wherein the first material layers in material are different from the second material layers. A pair of first spacers is disposed on a top layer of the second material layers at the first edge region. A pair of second spacers is disposed on a top layer of the first material layers at the second edge region. A first insulating layer is disposed on the top layer of the second material layers between the pair of the first spacers. A second insulating layer is disposed on the top layer of the first material layers between the pair of the second spacers. A first work-function metal layer fills between the first spacers and the first inner spacers at the first device region. A second work-function metal layer fills between the second spacers and the second inner spacers at the second device region. A pair of first electrode layers is disposed on the substrate at both outer sides of the first inner spacers. A pair of second electrode layers is disposed on the substrate at both outer sides of the second inner spacers.

In an embodiment, as to the nanosheet device, materials of the first/second material layers include SiGe/Si, Ge/GaAs, or GaAs/AlAs.

In an embodiment, as to the nanosheet device, a bottom one of the first material layers is separated from the substrate by a pair of the inner spacers.

In an embodiment, as to the nanosheet device, a bottom one of the second material layers is disposed on the substrate.

In an embodiment, as to the nanosheet device, a thickness of the first and second spacers is substantially equal to a thickness of the first and second inner spacers.

In an embodiment, as to the nanosheet device, a thickness of the first and second spacers is different from a thickness of the first and second inner spacers.

In an embodiment, as to the nanosheet device, a number of the first material layers at the first device region is less by one than a number of the second material layers at the second device region.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1G are drawings, schematically illustrating a method to fabricate a nanosheet field effect transistor (FET) in a perspective view, according to an embodiment of the invention.

FIG. 2 is a drawing, schematically illustrating a cross-sectional structure in FIG. 1G.

FIG. 3 is a drawing, schematically illustrating a cross-sectional structure in fabrication subsequent to the structure in FIG. 2.

FIG. 4 to FIG. 12 are drawings, schematically illustrating a method for fabricating nanosheet field effect transistor in CMOS device in cross-sectional views, according to an embodiment of the invention.

### DESCRIPTION OF THE EMBODIMENTS

The invention provides a method to form the nanosheet transistor, on which the inner spacers can be efficiently formed so to support the nanowires for the channel. The invention can also be applied to the CMOS fabrication process.

Several embodiments are provided for describing the invention. However, the invention is not just limited to the embodiments as provided.

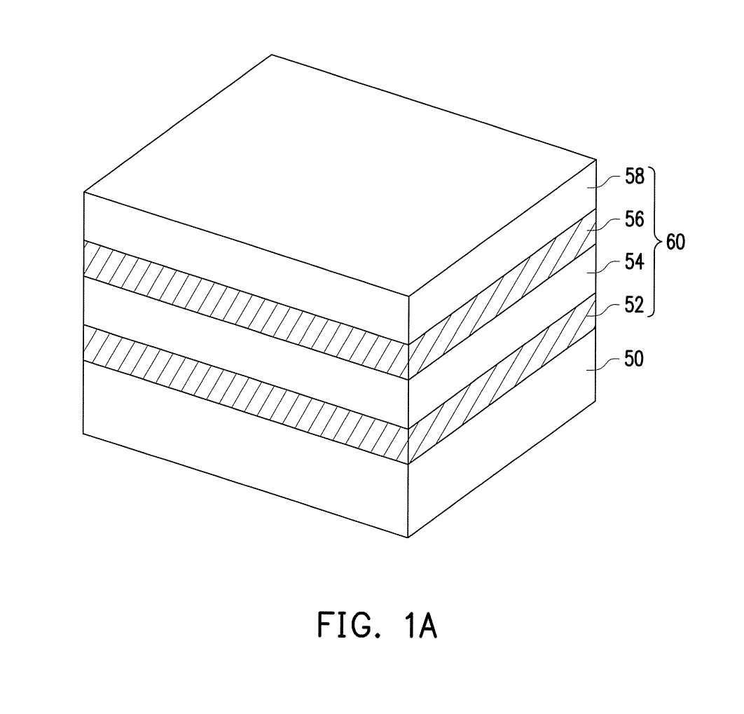

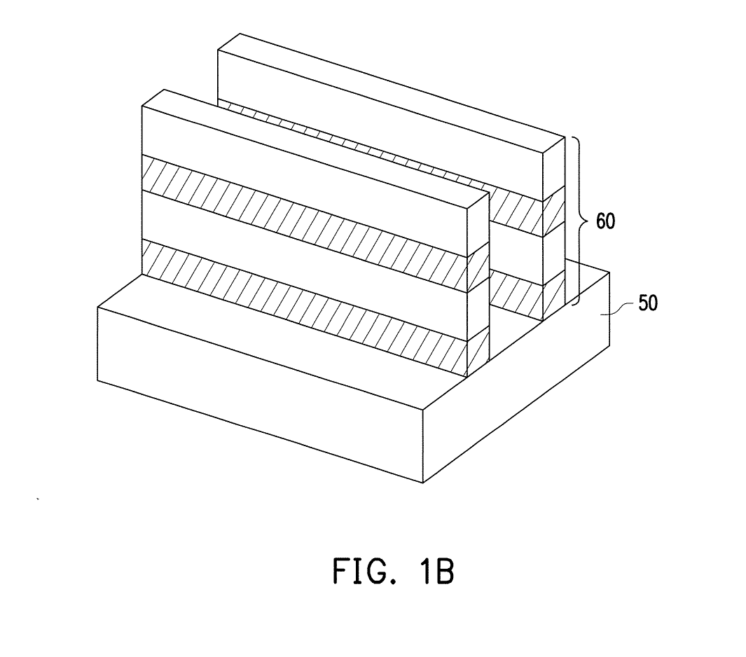

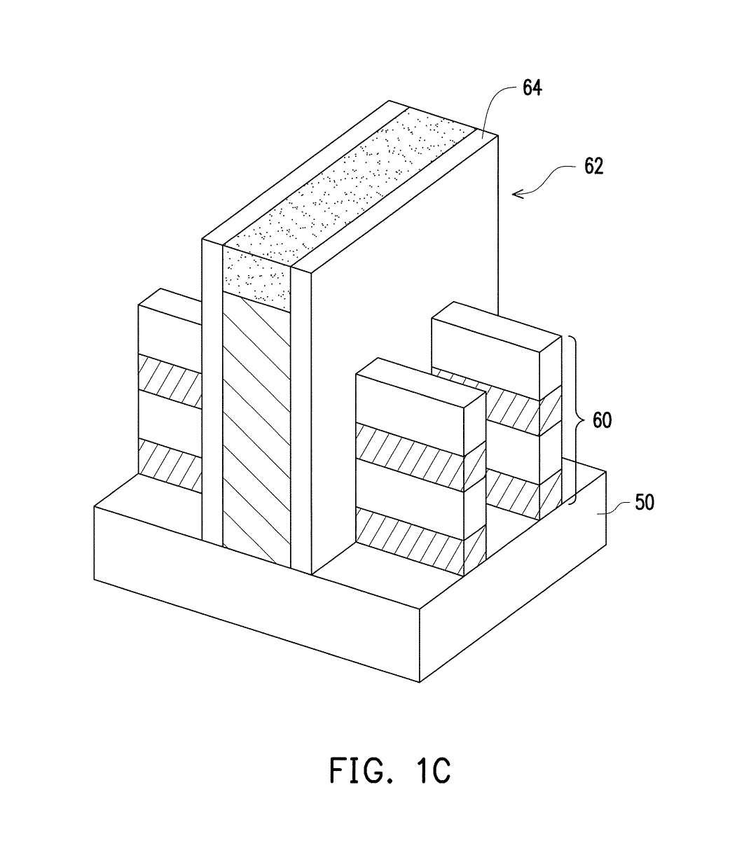

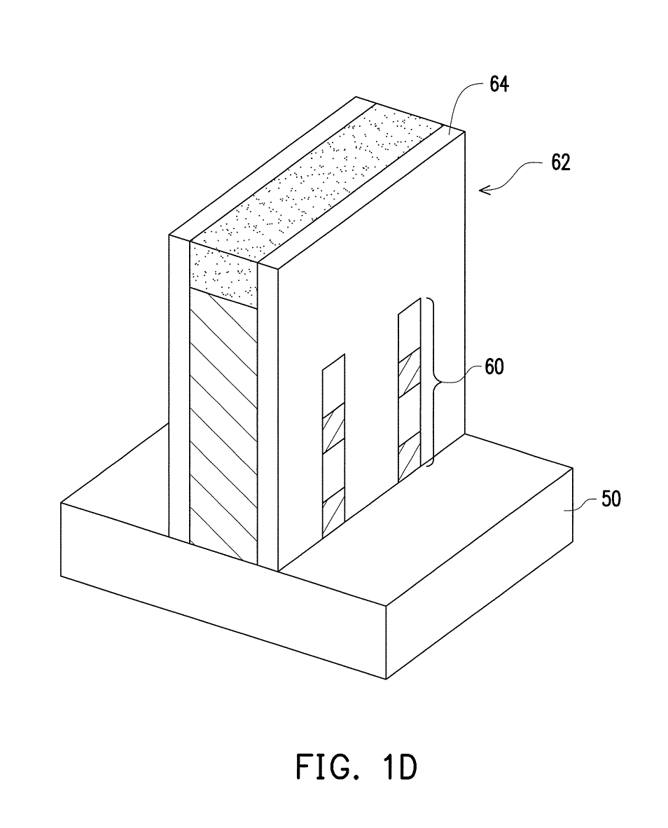

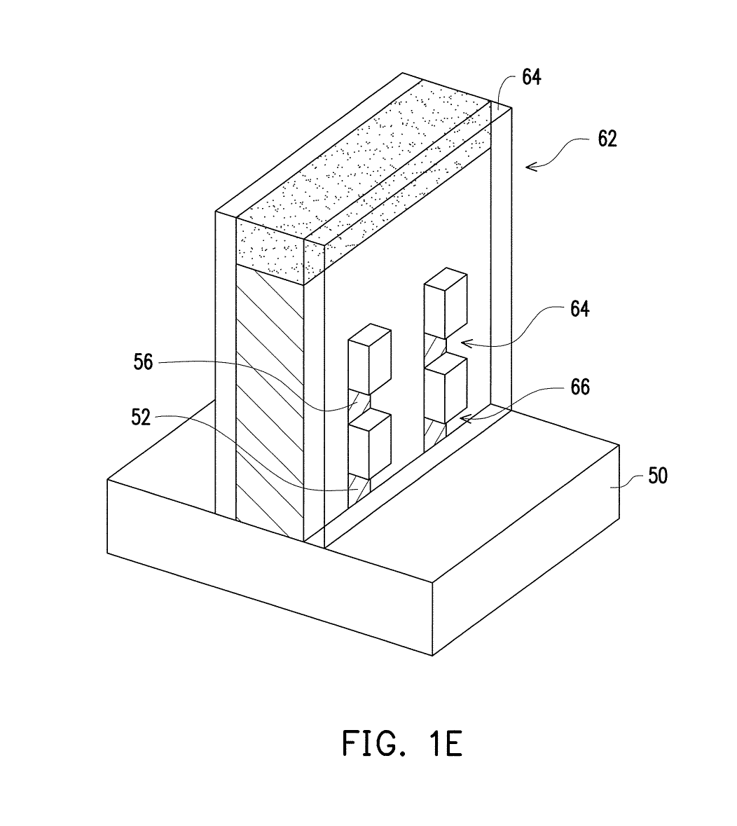

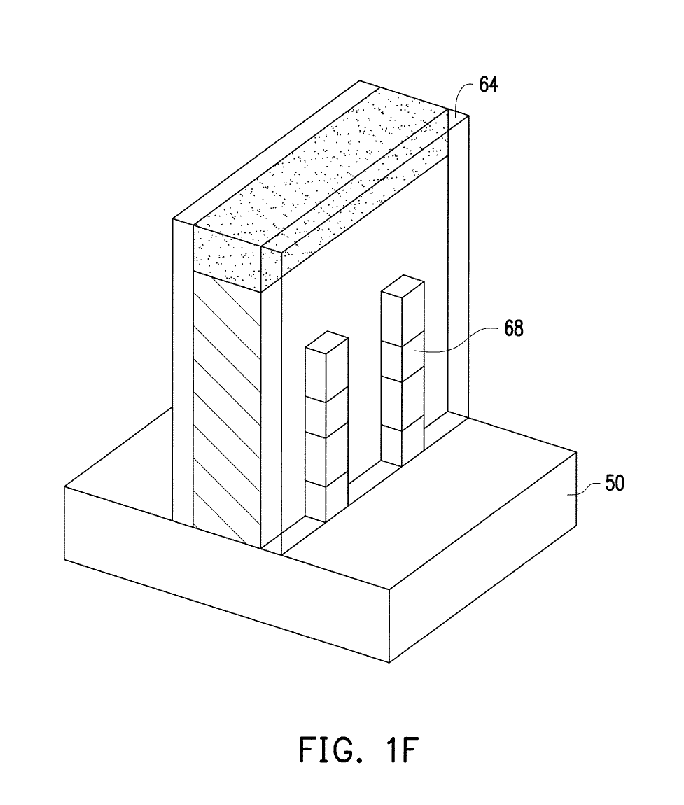

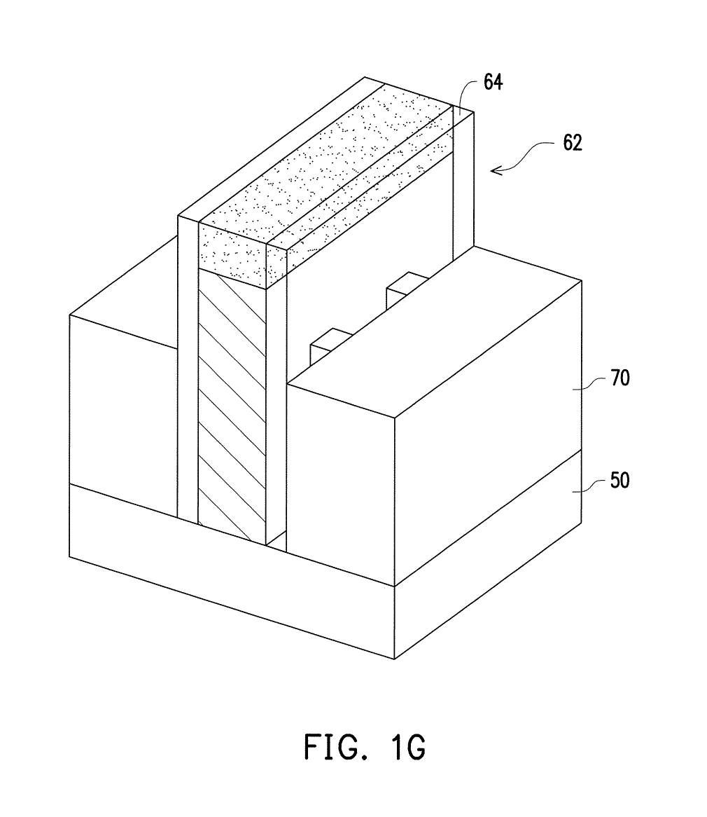

FIG. 1A to FIG. 1G are a drawing, schematically illustrating a method to fabricate a nanosheet field effect transistor (FET), according to an embodiment of the invention.

As a general view on the nanosheet FET, referring to FIG. 1A, a nanosheet FET can be fabricated by forming a stacked layer 60 on a substrate 50. The stacked layer 60 includes multiple material layers 52, 54, 56, 58, stacked up on the substrate 50. Two kinds of materials are alternatingly adapted for the material layers in the stacked layer 60, in an example. The choices of the materials for the material layer 52(56)/54(58) can be SiGe/Si, Ge/GaAs, or GaAs/AlAs, as an example, but not limited to.

Referring to FIG. 1B, the stacked layer 60 is patterned to have the fin stacked in fin line. The stacked layer 60 in fin line is extending along a direction. Referring to FIG. 1C, a dummy gate line structure 62, having the spacer 64 at both sidewalls, is formed over the stacked layer 60 in fin line. In FIG. 1D, the dummy gate line structure 62 is used as an etching mask, an etching back process can be performed to etch the stacked layer 60 in fin line. In FIG. 1E, the material layers 52 and 56 of the stacked layer 60 are laterally etched to have indent portions 64, 66. Here, one spacer 64 is shown in transparent manner, so to see the inner structure of the indent portions 64, 66. In FIG. 1F, inner spacers 68 are then formed to fill the indent portions 64, 66. In FIG. 1G, a source/drain (S/D) layers 70 are formed on the substrate 50 at both sides of the dummy gate line structure 62.

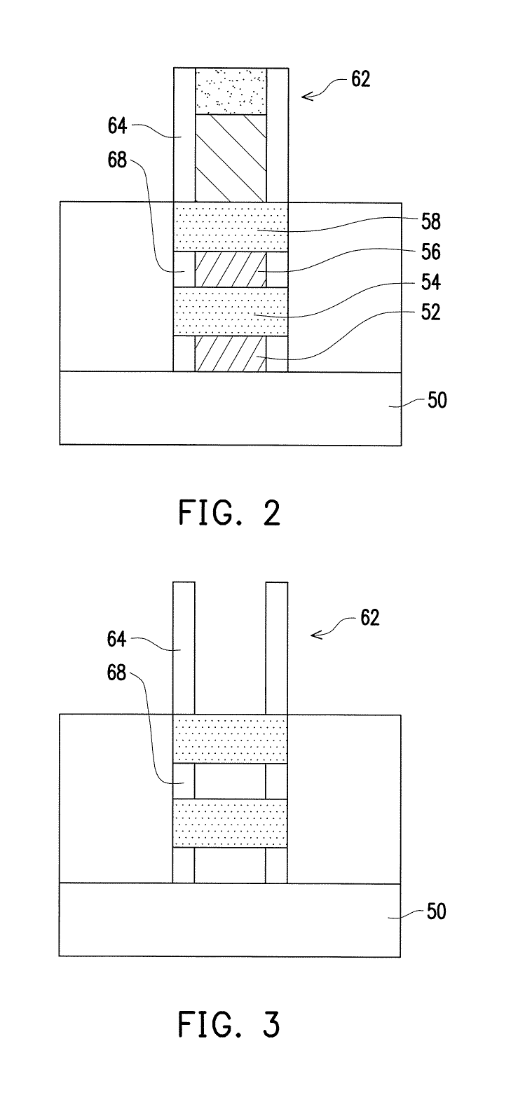

FIG. 2 is a drawing, schematically illustrating a cross-sectional structure in FIG. 1G. Referring to FIG. 2, as to the cross-section structure along the stacked layer 60 in fine line, the material layers 58 remain between the source/drain (S/D) layers 70. However, the material layers 52 and 56 are disposed between the pair of inner spacer 66.

FIG. 3 is a drawing, schematically illustrating a cross-sectional structure in fabrication subsequent to the structure in FIG. 2. Referring to FIG. 3, since the dummy gate line 60 is not the actual gate line as needed, the material between the spacer 64 is etched away. In addition, the material layers 52 and 56 between the inner spacers 68 are also remove by proper etching process. Then, the materials actually used for the gate line can be formed to fill the space between the spacers 64 and the inner spacer 68.

The processes subsequent to FIG. 3 are not further described here in this embodiment. However, another embodiment to form the CMOS device is further provided as follows.

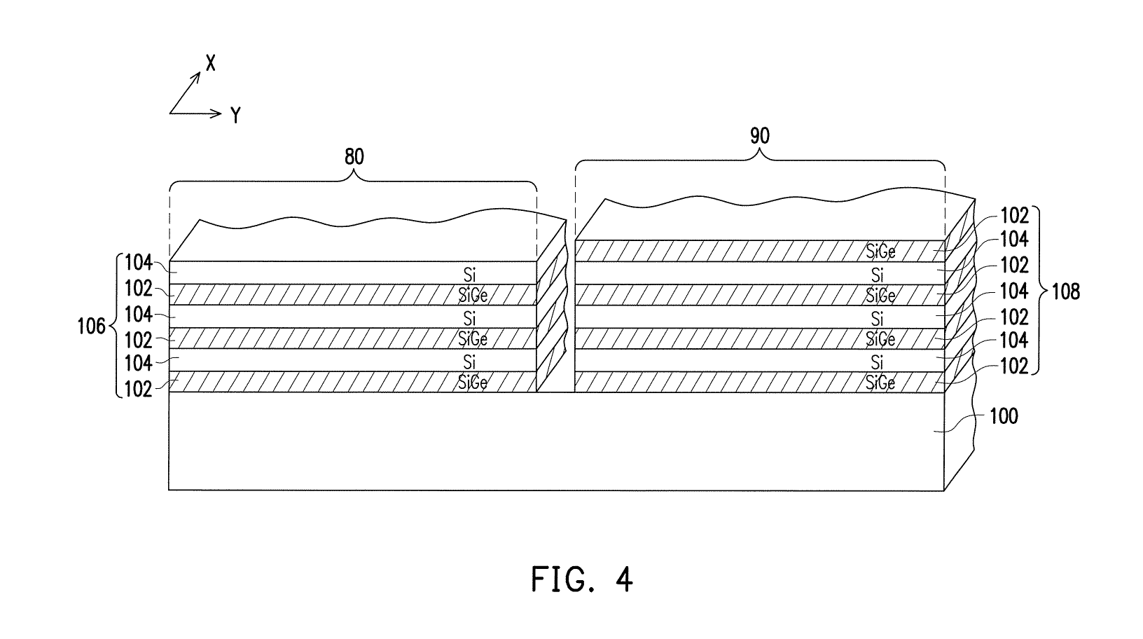

FIG. 4 to FIG. 12 are drawings, schematically illustrating a method for fabricating nanosheet field effect transistor in CMOS device in cross-sectional views, according to an embodiment of the invention.

Referring to FIG. 4, a substrate 100, such as silicon substrate, is provided, on which an N-type device region 80 and a P-type device region 90 are defined. In the embodiment, the CMOS structure is shown. However, N-type device region 80 or the P-type device region 90 can be processed if the NMOS or the PMOS is separately formed.

In the embodiment, a stacked layer 106 is formed in the N-type device region 80 and the P-type device region 90. The stacked layer 106 is formed by first material layers 102 and second material layers 104, which are alternatingly stacked up.

In the embodiment, the material of the first material layer 102 is suitable for forming P-type FET and the material of the second material layer 104 is suitable for forming N-type FET. The choices of the materials for the first/second material layer 102, 104 can be SiGe/Si, Ge/GaAs, or GaAs/AlAs, as an example, but not limited to.

To the P-type FET in the P-type device region 90, a material layer 102 can be additionally formed at top to form the stacked layer 108 to distinct from the stacked layer 106. The coordinate of X and Y are also shown just for easy description.

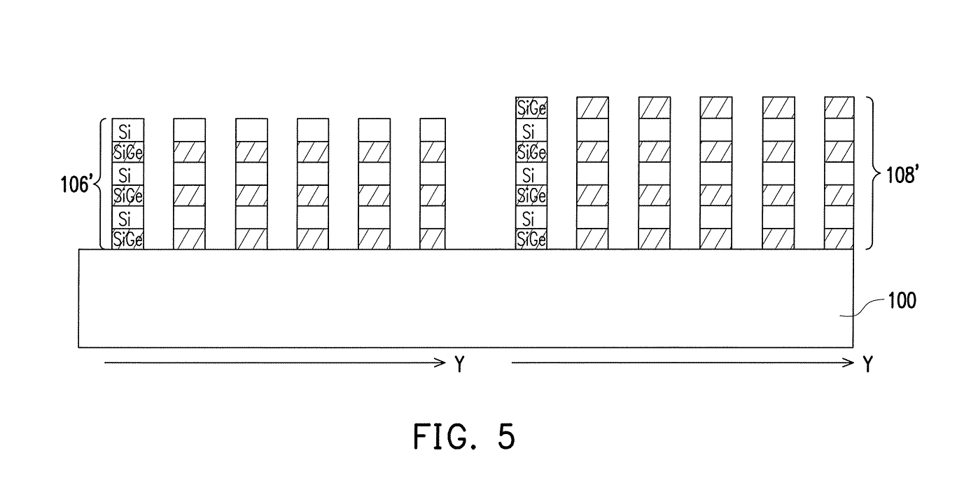

Referring to FIG. 5, the stacked layer 106 and the stacked layer 108 are patterned to form the stacked fins 106′ at the N-type device region and the stacked fins 108′ ate the P-type device region 90. As viewed along the cutting line along the Y axis, the stacked fins 106′ and the stacked fins 108s are like the columns.

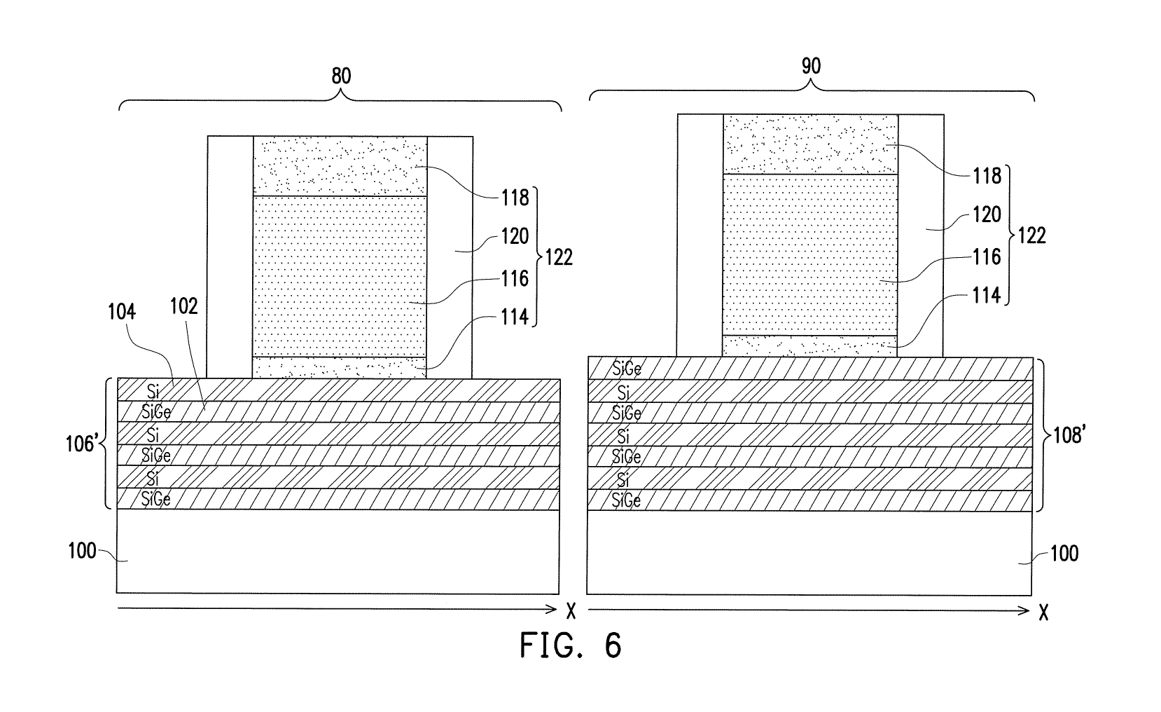

Referring to FIG. 6, as viewed along the cutting line along the X axis, the stacked fins 106′ and the stacked fins 108′ are like a sheet, such as the nanosheet. Then, a dummy stack 122 is formed over the substrate 100 along the Y-axis direction, crossing over the stacked fins 106′ and the stacked fins 108′. The dummy stack 122 in an example includes an insulating layer 114, a dummy gate 116, a mask layer 118, and spacers 120 at both sidewalls of the dummy gate 116. In an embodiment, the dummy stack 122 is a line crossing the stacked fins 106′ and the stacked fins 108′, as also seen in FIG. 1G as an example.

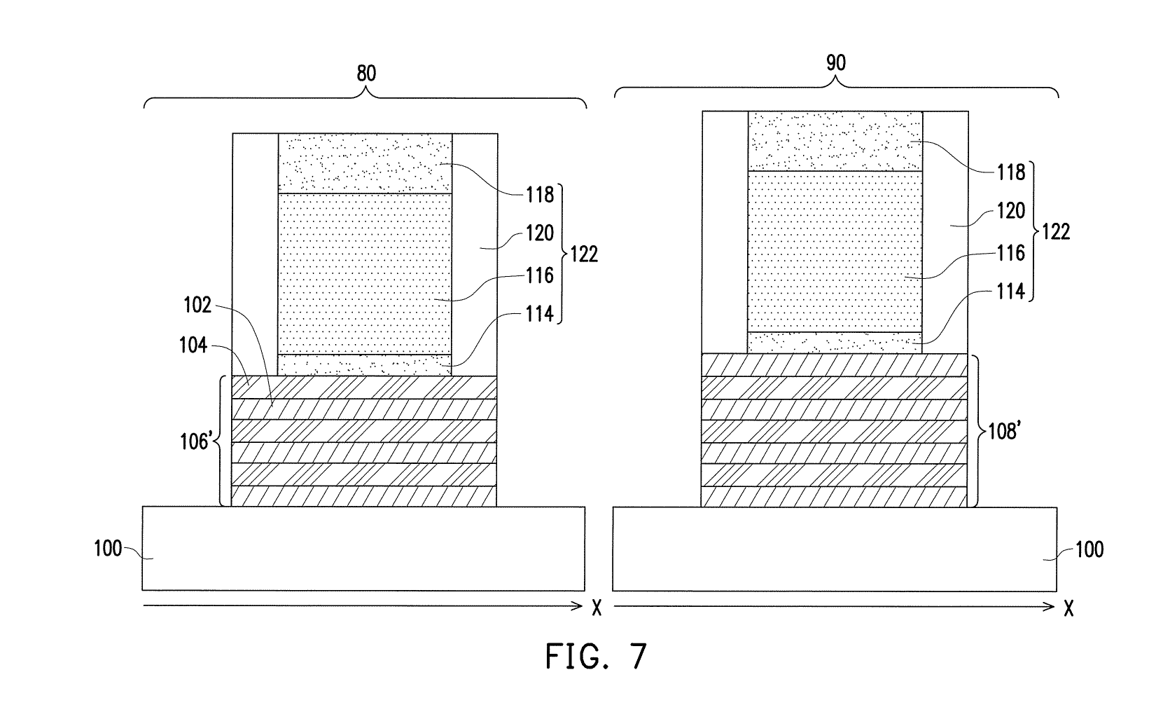

Referring to FIG. 7, an etching back process is performed, in which the dummy stack 122 is used as the etching mask. The portion of the stacked fins 106′ and the stacked fins 108′ not covered by the dummy stack 122 is etched until the substrate 100 is exposed at this etching portion. A proper etchant has been used here without detail in descriptions.

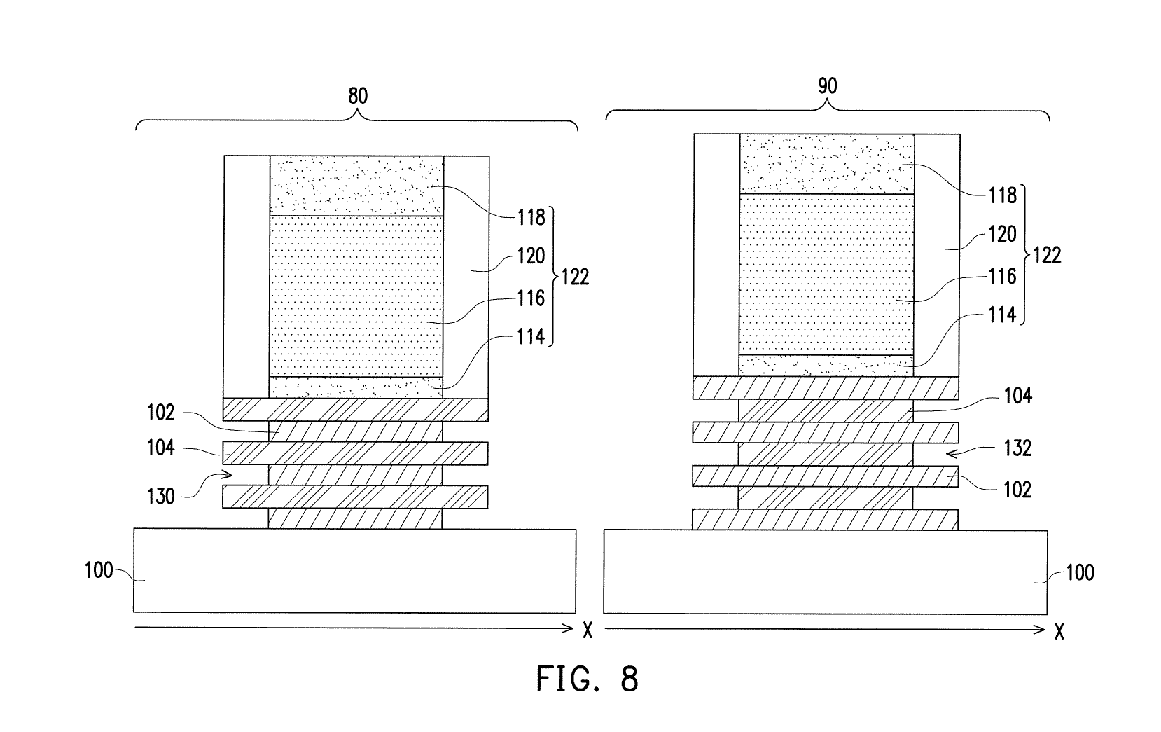

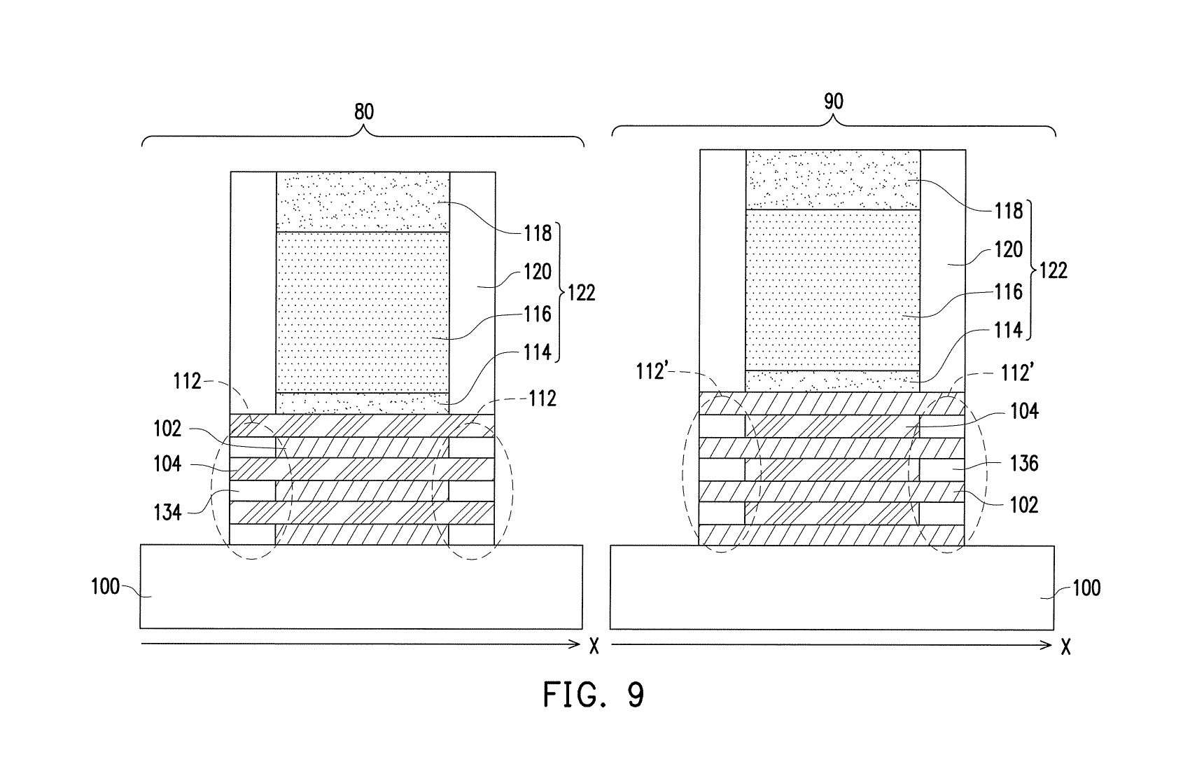

Referring to FIG. 8, after the etching back process, the sidewalls of the first/second material layers 102, 104 are exposed, as well. Then, a lateral etching process is performed with the proper etchant with the etching selection ratio, the first material layer 102, such as SiGe, is etched to have the indent portion 130 at the N-type device region 80. However, different etchant is used to etch the second material layer 104, such as Si, so to have the indent portion 132 at the P-type device region 90. In an example, the photoresist layer may be used to cover the device region, which is not etched.

Referring to FIG. 9, the inner spacers 134, 136 with the proper material such as silicon nitride or any proper dielectric material for formed to fill the indent portions 130, 132. The thickness of the inner spacers 134, 136 can be equal or different to the thickness of the spacer 120. The inner spacers 134, 136 are under the spacers 120 at the edge regions 112, 112′ in the N-type device region 80 and the P-type device region 90. In an embodiment, the inner spacers can be formed by depositing a conformal material layer by atomic layer deposition (ALD) process and then the material layer may be subjected to an anisotropic dry etching process to remove the portion of the material layer not covered by the dummy stack 122. In an embodiment, the material of the inner spacers may be silicon nitride (SiN), silicon carbon nitride (SiCN), silicon oxynitride (SiON), or silicon boron carbon nitride (SiBCN).

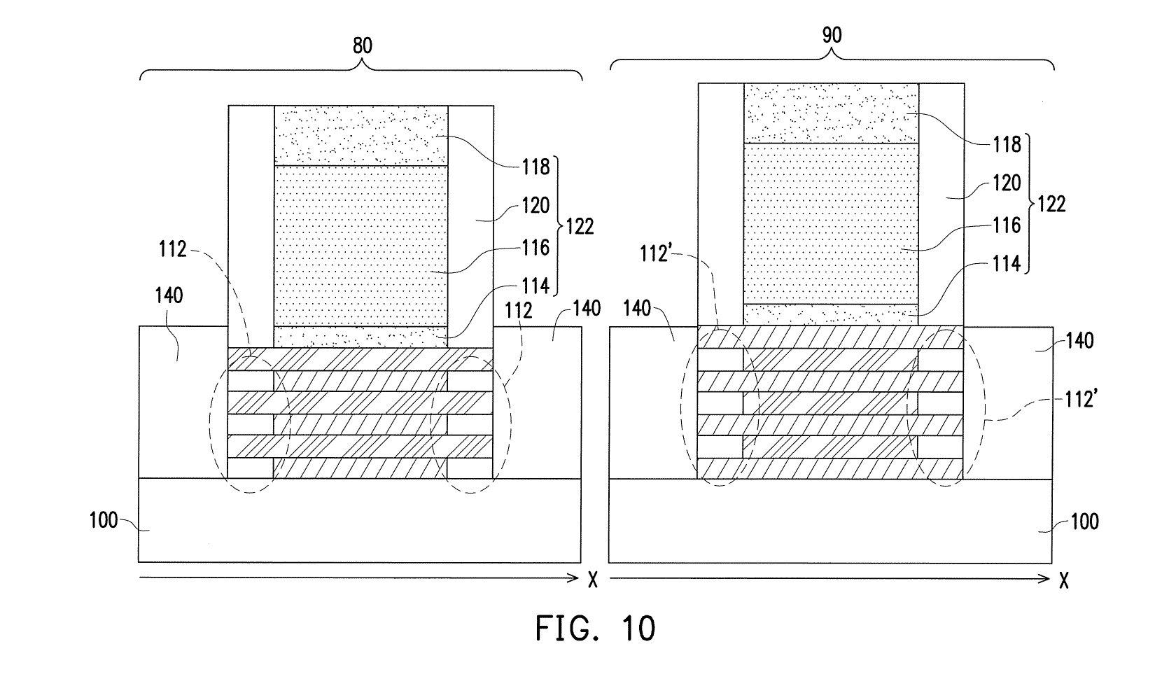

Referring to FIG. 10, a S/D layer 140 is formed on the substrate 100 at both side of the dummy gate 122 in the N-type device region 80 and the P-type device region 90, respectively.

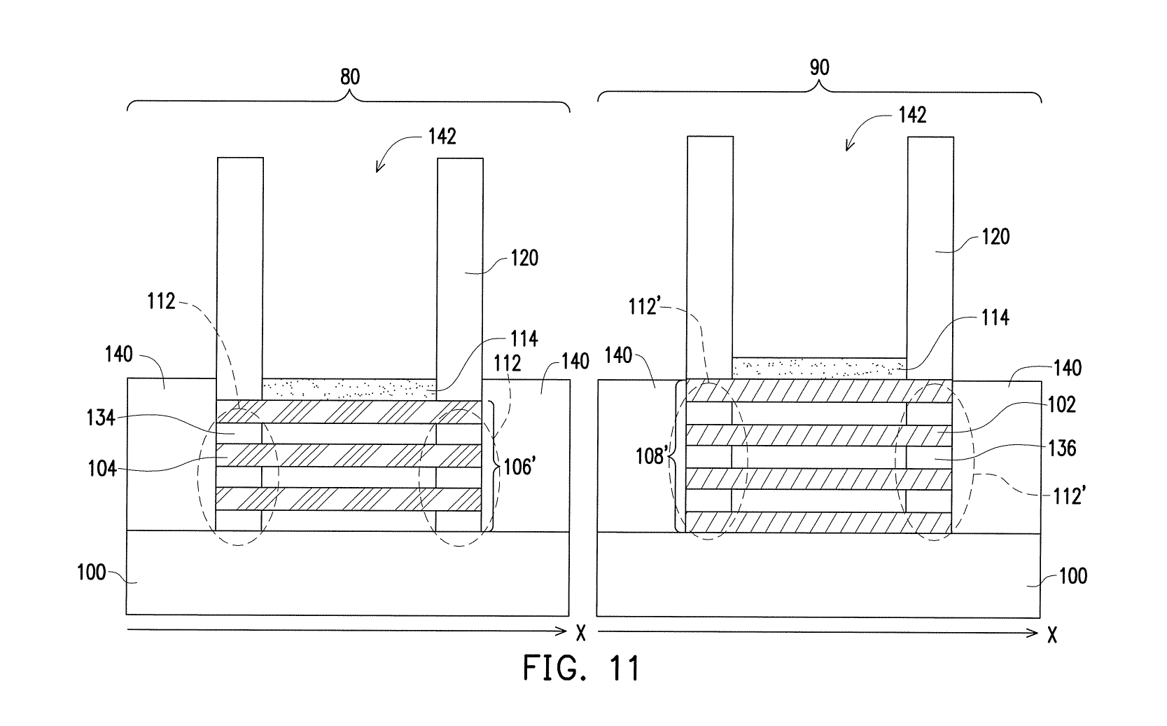

Referring to FIG. 11, using the proper etching process, such as wet etching or associating with a dry etching if it is necessary, with the proper choices of etchants, the etching process is performed. As a result, the dummy gate 116, a mask layer 118 between the spacers 120 are removed. Further, the first material layer 102 between the inner spacer 134 at the N-type device region 80 is removed, and also the second material layer 104 between the inner spacer 136 at the P-type device region 90 is removed. A free space 142 is the existing between a pair of the spacers 120 and pairs of the inner spacers 134 and pairs of the inner spacers 136. The insulating layer 114 remains or can be removed in an alternative embodiment.

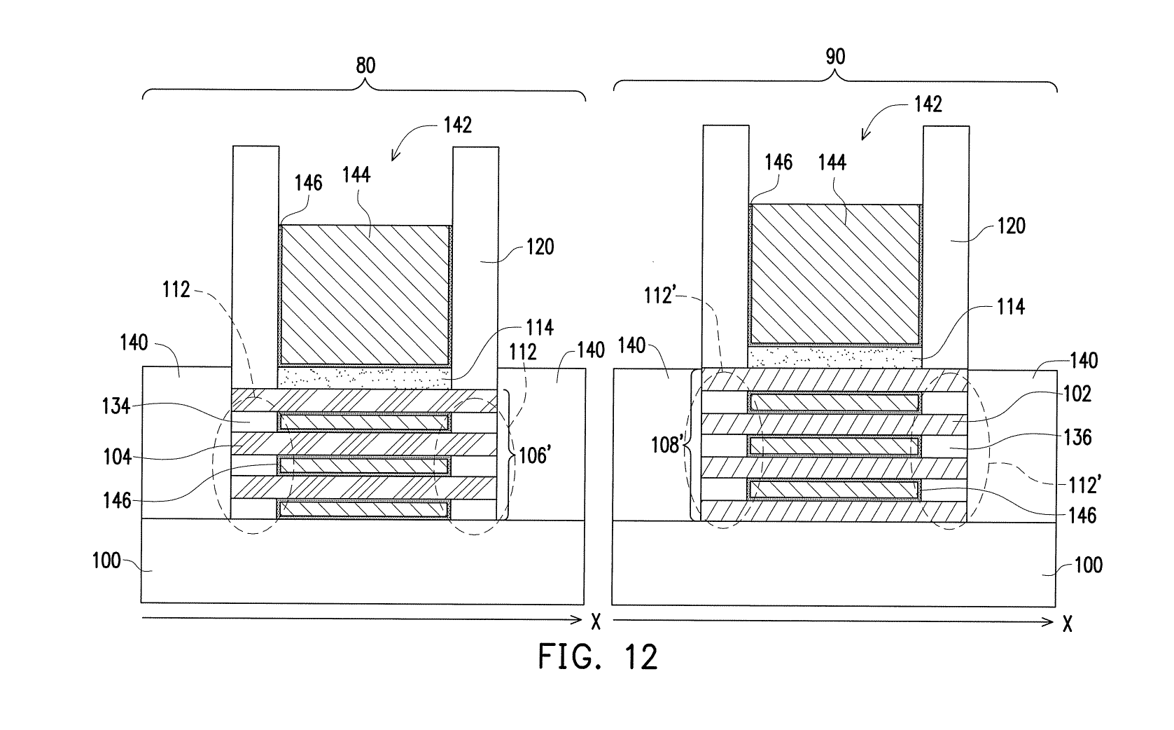

Referring to FIG. 12, a high-K dielectric layer 146 in an example can also be formed, including a portion surrounding the first material layer 102 at the P-type device region 90 and the second material layer 104 at the N-type device region 80 to serve as the gate insulating layer. The high-K dielectric layer 146 in an example can be formed on the inner sidewall of the spacers 120 and the top surface of the insulating layer 114. Then, a metal layer 144 serving as the gate terminal is formed to fill the free space 142 between the spacers 120 and the inner spacers 134, 136. The stacked structure of the previous stacked fin 106′, 108′ has been changed, in which the metal layer 144 replaces the first material layer 102 at the N-type device region 80 and likewise the metal layer 144 replaces the second material layer 104 at the P-type device region 90.

As a result, the FET has narrow width along the Y axis direction, to form a nanosheet structure, providing the channel of the FET. In an embodiment, N-type and P-type nanosheet FET are formed, in which the CMOS device can be formed. The inner spacers 134, 136 in the invention can be easily formed; to form the sheet structure.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method for fabricating nanosheet device, comprising:
providing a substrate;
forming a stacked layer on the substrate, having a plurality of first material layers and a plurality of second material layers in different materials, alternatingly stacked up;
patterning the stacked layer to form a stacked fin;
forming a dummy stack on the stacked fin, wherein the dummy stack comprises an insulating layer and a dummy gate sequentially stacked on the stacked fin and a pair of spacers on sidewalls of the dummy gate;
performing an etching back process with the dummy stack serving as an etching mask to etch the stacked fin and expose the substrate;
laterally etching a selected one of the first material layers and the second material layers, to have a pair of indent portions;
forming a pair of inner spacers to fill the indent portions;
forming a first source/drain layer and a second source/drain layer on the substrate at both sides of the dummy stack;
performing an etching process to remove the dummy gate of the dummy stack and the selected one of the first material layers and the second material layers between the inner spacers; and
forming a metal layer, filling between the spacers and the inner spacers.

2. The method of claim 1, wherein a thickness of the spacer and a thickness of the inner spacer are substantially equal.

3. The method of claim 1, wherein a thickness of the spacer and a thickness of the inner spacer are different.

4. The method of claim 1, wherein a number of the first material layers is equal to a number of the second material layers.

5. The method of claim 1, wherein a number of the first material layers is equal to a number of the second material layers, or greater than the number of the second material layers by one.

6. The method of claim 1, wherein the first/second material layers include SiGe/Si, Ge/GaAs, or GaAs/AlAs.

7. The method of claim 1, wherein the nanosheet device is an N-type metal-oxide-semiconductor (MOS) device, an P-type NMOS device, or a complementary MOS (CMOS) device.

8. The method of claim 1, wherein the step of performing the etching process comprises a dry etching with a first etchant and a wet etching with a second etchant.

9. A method for fabricating a nanosheet device, comprising:
providing a substrate, having an N-type device region and a P-type device region;
forming a stacked layer on the substrate, having a plurality of first material layers and a plurality of second material layers with different material but in equal number, alternatingly stacked over the substrate;
forming a top first material layer on the stacked layer at the P-type device region;
patterning the stacked layer at an N-type device region to form a first stacked fin, and the stacked layer with the top first material layer at the P-type device region to form a second stacked fin;
forming a dummy stack on the first stacked fin and the second stacked fin, wherein the dummy stack comprises an insulating layer and a dummy gate sequentially stacked on the first and second stacked fins and a pair of spacers on sidewalls of the dummy gate;
performing an etching back process with the dummy stack serving as an etching mask to etch the first and second stacked fins and expose the substrate;
laterally etching the first material layers of the first stacked fin to have a pair of first indent portions;
laterally etching the second material layers of the second stacked fin to have a pair of second indent portions;
forming a pair of first inner spacers to fill the first indent portions and a pair of second inner spacers to fill the second indent portions;
forming a first source/drain layer and a second source/drain layer on the substrate at both sides of the dummy stack;
performing an etching process to remove the dummy gate of the dummy stack and the first material layers between the first inner spacers at the N-type device region, and remove the dummy gate of the dummy stack and the second material layers between the second inner spacers at the P-type device region; and
forming a metal layer, filling between the spacers and the first inner spacers at the N-type device region and between the spacers and the second inner spacers at the P-type device region.

10. The method of claim 9, wherein a thickness of the first and second spacers is substantially equal to a thickness of the first and second inner spacers.

11. The method of claim 9, wherein a thickness of the first and second spacers is different from a thickness of the first and second inner spacers.

12. The method of claim 9, wherein the first/second material layers include SiGe/Si, Ge/GaAs, or GaAs/AlAs.

13. The method of claim 9, wherein the step of performing the etching process comprises a dry etching with a first etchant and a wet etching with a second etchant.

14. A nanosheet device, comprising:
a substrate, having a first device region and a second device region;
a plurality of second material layers at the first device region, stacked with a plurality of first inner spacers at a first edge region, wherein a first one of the first inner spacers is disposed on the substrate;
a plurality of first material layers at the second device region, stacked with a plurality of second inner spacers at a second edge region, wherein a first one of the first material layers is disposed on the substrate, wherein the first material layers in material are different from the second material layers;
a pair of first spacers disposed on a top layer of the second material layers at the first edge region;
a pair of second spacers disposed on a top layer of the first material layers at the second edge region;
a first insulating layer, disposed on the top layer of the second material layers between the pair of the first spacers;
a second insulating layer, disposed on the top layer of the first material layers between the pair of the second spacers;
a first metal layer, filled between the first spacers and the first inner spacers at the first device region;
a second metal layer, filled between the second spacers and the second inner spacers at the second device region;
a pair of first electrode layers, disposed on the substrate at both outer sides of the first inner spacers; and
a pair of second electrode layers, disposed on the substrate at both outer sides of the second inner spacers.

15. The nanosheet device of claim 14, wherein materials of the first/second material layers include SiGe/Si, Ge/GaAs, or GaAs/AlAs.

16. The nanosheet device of claim 15, wherein a bottom one of the first material layers is separated from the substrate by a pair of the inner spacers.

17. The nanosheet device of claim 15, wherein a bottom one of the second material layers is disposed on the substrate.

18. The nanosheet device of claim 14, wherein a thickness of the first and second spacers is substantially equal to a thickness of the first and second inner spacers.

19. The nanosheet device of claim 14, wherein a thickness of the first and second spacers is different from a thickness of the first and second inner spacers.

20. The nanosheet device of claim 14, wherein a number of the first material layers at the first device region is less by one than a number of the second material layers at the second device region.
